(19) United States
(12) Patent Application Publication
(10) Pub. No.: US 2025/0212504 A1
(43) Pub. Date: Jun. 26, 2025

(54) Method for Producing Nanosheet Transistors

(71) Applicant: IMEC VZW, Leuven (BE)

(72) Inventors: Geert Hellings, Halle (BE); Juergen Boemmels, Heverlee (BE); Julien Ryckaert, Tervuren (BE)

(21) Appl. No.: 18/969,807

(22) Filed: Dec. 5, 2024

(30) Foreign Application Priority Data
Dec. 21, 2023 (EP) 23219037.1

(51) Int. Cl. H10D 84/83; H10D 84/01

(52) U.S. Cl. CPC H10D 84/833; H10D 84/0167; H10D 84/017; H10D 84/0186; H10D 84/0188

(57) ABSTRACT

A fin-shaped structure formed on a base substrate that could comprise a stack of alternating sacrificial layers and semiconductor layers. The stack materials could be removed relative to the dummy gates and relative to a mask formed before or after the dummy gates, creating lateral recesses with U-shaped sidewalls formed of stacked U-shaped portions of the sacrificial and semiconductor layers. Semiconductor material could be grown in the recesses by epitaxial growth, starting from the U-shaped semiconductor portions. The grown material could be lattice mismatched relative to the material of the U-shaped portions. No dislocations could be created due to oppositely interfering growth fronts, and a desired stress can thereby be created in at least one or more channel sheets of the eventual transistors. These transistors can be arranged in a forksheet configuration, after producing a trench to remove the mask, and filling the trench by a dielectric material.

### CROSS-REFERENCE TO RELATED APPLICATIONS

The present application is a non-provisional patent application claiming priority to EP 23219037.1, filed on Dec. 21, 2023, the contents of which are hereby incorporated by reference.

### FIELD OF THE DISCLOSURE

The present disclosure is related to semiconductor processing, in particular to the production of nanosheet transistors.

### BACKGROUND

Nanosheet technology represents one of the main answers to the limitations of Fin Field Effect Transistor (FinFET) technology in terms of the ongoing scaling requirements of active devices on an integrated circuit chip. In a standalone nanosheet transistor, a channel can be formed of one or more semiconductor sheets stacked one on top of the other, with the gate dielectric as well as the gate electrode wrapped around the sheets. The term ‘gate all around’ (GAA) is also used for this type of device. A further development is the forksheet configuration, wherein two nanosheet transistors are built on either side of a separating dielectric wall.

Nevertheless, further challenges need to be met in terms of improving and finetuning the performance of nanosheet transistors. One of the problems is related to the epitaxial growth of source and drain areas in between adjacent dummy gate structures. A plurality of fin-shaped structures may be formed from a stack of alternating sacrificial and semiconductor layers, for example SiGe alternated with Si. Dummy gates may then be produced transversally with respect to the fin structures, followed by the formation of outer and inner spacers. Then the material of the fins may be removed in between the dummy gates and source and drain areas may be formed by epitaxial growth, starting on the lateral surfaces of semiconductor layers within the fin structures. The growth may start on opposite sides of the trench formed between two adjacent dummy gates, and may continue until a bottom area of the trench is filled. This growth pattern may not be ideal in terms of obtaining stress in the eventual channel of the transistors, the stress being beneficial for optimizing the carrier mobility. The growth along two opposite fronts can result in close-to-zero channel stress, due to a dislocation plane forming where the two growth fronts meet. These dislocations may lead to relaxation defects propagating to the interface between the seed layer and the grown layer, thereby eliminating any strain built up in the grown layer.

### SUMMARY

The disclosure is related to a method for producing one or more nanosheet transistors in accordance with the appended claims. According to one example embodiment, a fin-shaped structure can be formed on a base substrate, the structure comprising a stack of alternating sacrificial layers and semiconductor layers, the latter being suitable for the formation of channel sheets in the eventual one or more transistors. The stack materials can be removed relative to the dummy gates and relative to a mask formed before or after the dummy gates, thereby creating lateral recesses with U-shaped sidewalls formed of stacked U-shaped portions of the sacrificial and semiconductor layers. Internal spacers may be formed between the U-shaped semiconductor portions. Semiconductor material can be grown in the recesses by epitaxial growth, starting from the U-shaped semiconductor portions. The grown material can be lattice mismatched relative to the channel material. By ‘lattice mismatched’ is meant that there can be a difference between the dimensions of the lattice structure of the channel material (acting as the seed layer of the epitaxial growth) and the grown material. Due to the nature of the epitaxial growth process, the lattice of the grown material may adapt to the lattice of the seed layer, so that the seed layer and the grown layer may be able to form a strained uniformly crystalline structure. Because of the growth mechanism starting from the U-shaped semiconductor portions, no dislocations may be created due to oppositely interfering growth fronts. Hence no relaxation defects originating in such growth fronts may be able to propagate to the interface between the seed layer and the grown layer, and a desired stress can thereby be created in at least one or more of the channel sheets of the eventual transistors. These transistors may be arranged in a forksheet configuration, after producing a trench to thereby remove the mask, and filling the trench by a dielectric material.

In another aspect, the disclosure relates to a method for producing one or more nano-sheet transistors. This method may include, on a base substrate, producing at least one fin-shaped structure extending in a longitudinal direction. The structure may comprise a stack of layers including one or more sacrificial layers and one or more crystalline semiconductor layers formed of a first semiconductor material, stacked in alternating order. This method may also include producing at least three mutually parallel and spaced apart dummy gate structures arranged transversely with respect to and fully overlapping the fin-shaped structure and the mask. This method may further include producing dielectric spacers at least on the sidewalls of the dummy gate structures. Moreover, this method may include patterning the stack of sacrificial and semiconductor layers by removing the material of the layers relative to the dummy gate structures and the spacers. Also this method may include, relative to a mask formed prior to or after producing the dummy gate structures and extending in the same longitudinal direction as the fin-shaped structure, so that two lateral recesses having U-shaped sidewalls may be formed in the stack on each side of at least one of the dummy gate structures having adjacent dummy gates on either side, the sidewalls comprising exposed U-shaped portions of the sacrificial and semiconductor layers, on the U-shaped sidewalls, producing inner spacers by etching back the exposed sacrificial material relative to the exposed semiconductor material. The method may include replacing the thereby removed sacrificial material by a dielectric material, by epitaxial growth. The method may also include growing a second semiconductor material in the lateral recesses, wherein the second semiconductor material can be lattice mismatched with respect to the first semiconductor material, and the second semiconductor material grows outward starting from the exposed U-shaped portions of the layers of the first semiconductor material. The growth may continue until a volume of the second semiconductor material can be obtained in each of the lateral recesses. The method may also include producing a dielectric layer that fills the spaces between every pair of adjacent dummy gate structures and planarizing the dielectric layer to a common level with the dummy gate structures. Further, the method may include, by lithography and etching, producing a trench along the longitudinal direction of the fin-shaped structure, the trench cutting through the dummy gate structures and the spacers, the trench being wider than the mask but narrower than the fin-shaped structure, so that the mask can be removed while leaving portions of the stack of alternating sacrificial and first semiconductor layers on either side of the trench. The method may include filling the trench with a dielectric material, thereby forming a dielectric wall. The method may also include removing the dummy gate structures and the remaining parts of the sacrificial layers, producing gate dielectric layers on the remaining parts of the first semiconductor layers and producing metal gates in direct contact with the gate dielectric layers on both sides of the dielectric wall. Moreover, the method may include producing electrical connections to at least one metal gate and two epitaxially grown volumes directly adjacent and on either side of the gate, thereby obtaining at least one nano-sheet transistor comprising a channel, a source area and a drain area.

According to an embodiment, the fin-shaped structure may comprise a dielectric layer directly on the base substrate and the stack of alternating sacrificial and semiconductor layers can be formed directly on the dielectric layer.

According to an embodiment, spacers may also be formed on the sidewalls of the mask and on the sidewalls of the fin-shaped structure.

According to an embodiment, the stack of alternating sacrificial and semiconductor layers may comprise at least two semiconductor layers and one epitaxially grown volume can be formed in each of the recesses, the volume being obtained by merged subvolumes growing outward from respective exposed U-shaped portions of the semiconductor layers.

According to an embodiment, the dielectric layer that fills the spaces between every pair of adjacent dummy gate structures can be removed after the step of producing the trench, and a continuous layer of dielectric material can be thereafter produced, the continuous layer filling the trench and the spaces between every pair of adjacent dummy gate structures.

According to an embodiment, the mask can be a hardmask formed on the fin-shaped structure and covering a central elongate portion of the structure, and the hardmask can be formed prior to the formation of the dummy gate structures.

According to an embodiment, the mask can be a hardmask or a resist mask formed after the formation of the dummy gates and covering a central elongate portion of the fin-shaped structure.

In another aspect, the disclosure is also related to a forksheet configuration that can comprise a base substrate, a dielectric wall and two nanosheet transistors on opposite sides of the dielectric wall, each of the transistors comprising one or more channel sheets, a metal gate, a gate dielectric between the channel sheets and the metal gate, a source and a drain area, characterized in that in any cross section parallel to the base substrate and through at least one of the channel sheets. The source and drain areas and the channel sheet through which the cross section is taken can be uniformly crystalline.

According to an embodiment of the forksheet configuration, a dielectric layer may lie directly on the base substrate and the dielectric wall. The transistors may be placed on the dielectric layer.

In another aspect, disclosure relates to a semiconductor component that may comprise one or more transistors produced according to the methods described, and to a semiconductor component that may comprise one or more forksheet configurations according to the methods described.

### BRIEF DESCRIPTION OF THE FIGURES

The above, as well as additional, features will be better understood through the following illustrative and non-limiting detailed description of example embodiments, with reference to the appended drawings.

FIG. 1 illustrates a step of a method, according to example embodiments.

FIG. 2 illustrates a step of a method, according to example embodiments.

FIG. 3 illustrates a step of a method, according to example embodiments.

FIG. 4 illustrates a step of a method, according to example embodiments.

FIG. 5 illustrates a step of a method, according to example embodiments.

FIG. 6 illustrates a step of a method, according to example embodiments.

FIG. 7 illustrates a step of a method, according to example embodiments.

FIG. 8 illustrates a step of a method, according to example embodiments.

FIG. 9 illustrates a step of a method, according to example embodiments.

FIG. 10 illustrates a step of a method, according to example embodiments.

FIG. 11 illustrates a step of a method, according to example embodiments.

FIG. 12 illustrates a step of a method, according to example embodiments.

FIG. 13 illustrates a step of a method, according to example embodiments.

FIG. 14 illustrates a step of a method, according to example embodiments.

FIG. 15 illustrates a step of a method, according to example embodiments.

FIG. 16 illustrates a step of a method, according to example embodiments.

FIG. 17 illustrates a step of a method, according to example embodiments.

FIG. 18 illustrates a step of a method, according to example embodiments.

All the figures are schematic, not necessarily to scale, and generally only show parts which are necessary to elucidate example embodiments, wherein other parts may be omitted or merely suggested.

### DETAILED DESCRIPTION

Example embodiments will now be described more fully hereinafter with reference to the accompanying drawings. That which is encompassed by the claims may, however, be embodied in many different forms and should not be construed as limited to the embodiments set forth herein; rather, these embodiments are provided by way of example. Furthermore, like numbers refer to the same or similar elements or components throughout.

One embodiment will be described hereafter in some detail. Every reference to materials and dimensions is made only by way of example and is not intended to be limiting.

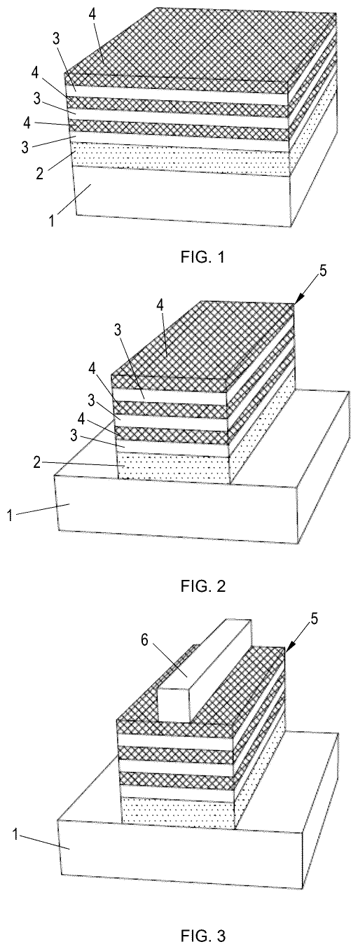

FIG. 1 shows a small portion of a base substrate 1 comprising a number of layers on its upper surface. The base substrate 1 may be a standard silicon process wafer having a diameter of 300 mm and a thickness between 0.4 and 0.5 mm. Only a thin upper portion of the wafer is shown, which may have a thickness in the order of 10-20 nm. Directly on the Si substrate can be a silicon oxide layer (SiO₂) 2 of about 10 nm thick. On this SiO₂ layer 2, a stack of alternating SiGe layers 3 and Si layers 4 can be present, each having a thickness of about 5 nm. The stack can start with a SiGe layer 3 at the bottom and/or end with a Si layer 4 at the top. When producing nanosheet devices, as well as in the method according to the illustrated embodiment, the SiGe sheets can have the function of sacrificial layers, to be removed at a later stage of the process. The Si layers may be formed of crystalline Si. In some example embodiments, this can be realized by producing the subsequent SiGe and Si layers by epitaxial growth.

By lithography and etching of the SiGe and Si layers 3,4 and the SiO₂ layer 2, a fin-shaped structure 5 can be formed, as illustrated in FIG. 2, which may comprise the patterned stack of a SiO₂ layer 2 and alternating SiGe and Si layers 3,4. Only one fin-shaped structure 5 is shown, but in some implementations, it could be beneficial to produce an array of multiple mutually parallel fin-shaped structures 5 of equal width and constant pitch. The width of the fin-shaped structure 5 can be about 40 nm, but other widths are possible.

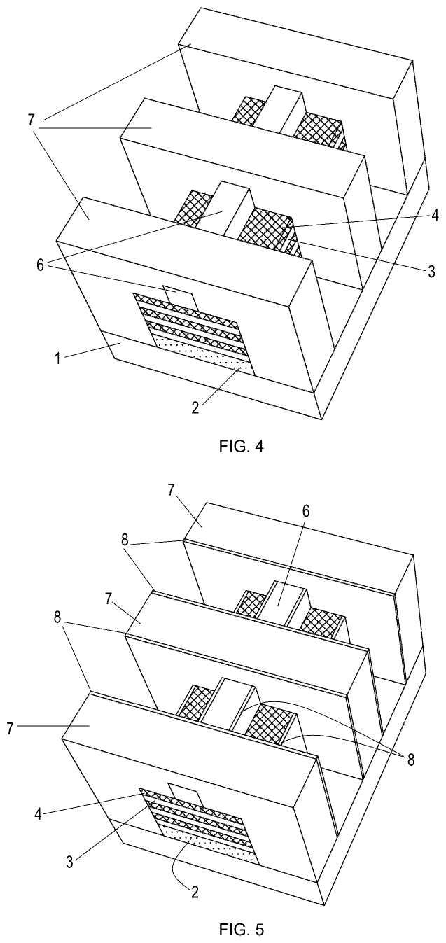

As illustrated in FIG. 3, a hardmask 6 can be then formed on top of the fin-shaped structure 5. This may be done by depositing a layer of hardmask material, for example SiN or SiC, and patterning the layer so that the mask 6 remains in the form of an elongate strip of mask material aligned to and on top of the fin-shaped structure 5. The width of the hardmask 6 may be between 10 and 15 nm. In an example embodiment, the mask 6 could be arranged coaxially with the fin-shaped structure 5. The mask 6 can enable anisotropically etching the materials of the stack of SiGe and Si layers 3,4 (hereafter also referred to as ‘the SiGe/Si stack 3,4’) relative to the mask material.

With reference to FIG. 4, a regular array of dummy gate structures 7 (hereafter also referred to as ‘dummy gates’) can be formed transversely, possibly perpendicularly, with respect to the fin-shaped structure 5 and the mask 6. The width of the dummy gates 7 may be in the order of 10-15 nm. The material, for example amorphous silicon, and the production method of the dummy gates 7 may include a replacement metal gate (RMG) technique. The distance between two adjacent dummy gate structures 7 may be a little larger than the dummy gate width in the example shown. This distance may be in the same order of magnitude as the dummy gate width.

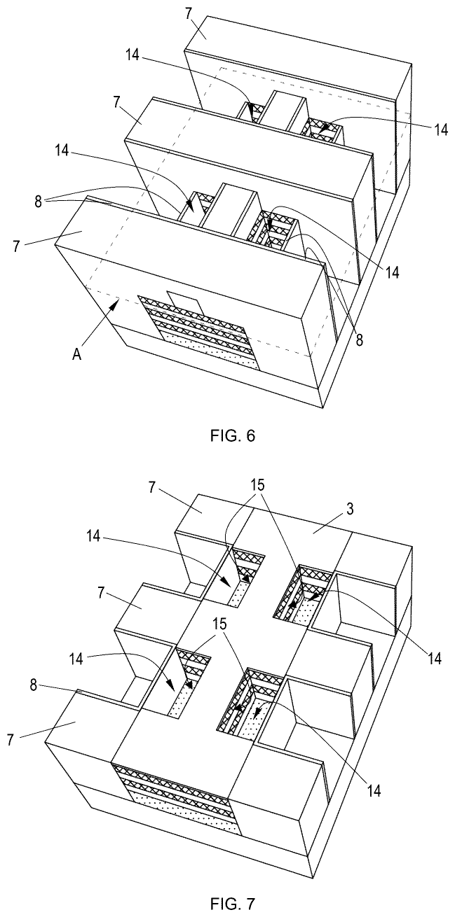

Then, as illustrated in FIG. 5, dielectric spacers 8 may be applied on the sidewalls of the dummy gate structures 7. The spacers 8 may have a thickness in the order of 1 to 5 nm for example. The spacers are not shown on the first and last of the three dummy gates illustrated in FIG. 5, in order to continue to visualize the fin-shaped structure 5, but it is to be understood that the spacers may be effectively formed on both sides of every dummy gate 7. The formation of the spacers 8 can be done by the conformal deposition of a thin dielectric layer, i.e. following the topography of the fin-structure 5, the mask 6 and the dummy gates 7, and removing the dielectric from the level surfaces by plasma etching. In the embodiment shown, spacers may be also formed on the sidewalls of the fin-shaped structure 5 and of the mask 6, in the areas between the dummy gate structures 7. Depending on the materials applied in the fin-shaped structure 5 and the mask 6 and/or on the process parameters applied for producing the spacers, it may be possible that no spacers may be formed here, or that the spacers may be only formed up to a given height. This may not have an influence on the methods described herein however, as will become apparent. The material of the spacers 8 may for example be SiN or SiCN.

The next step is illustrated in FIGS. 6 and 7. The material of the SiGe layers 3 and the Si layer 4 can be removed anisotropically relative to the dummy gate structures 7, the mask 6 and the dielectric spacers 8. The SiO₂ layer 2 may act as an etch stop layer or the etch process may be timed in order to stop without substantially removing the material of the SiO₂ layer 2. Multiple etch recipes with the appropriate etch selectivity for removing SiGe and Si relative to the various materials of the dummy gates 7, the mask 6 and the spacers 8 may be possible. This step can create lateral recesses 14 in the SiGe/Si stack 3,4, better visualized in FIG. 7, which shows a section by a plane A parallel to the base substrate 1 and intersecting one of the SiGe layers 3. The U-shaped sidewalls 15 of the lateral recesses 14 may be formed of U-shaped exposed portions of the SiGe and Si layers 3,4. In the image shown, the spacers 8 on the sides of the removed portions remain, forming a closure on the open end of the recesses 14. As stated above, it can be possible that no spacers or only partially formed spacers can be obtained at this location during the spacer formation process. In that case, the recesses 14 may be fully or partially open-ended.

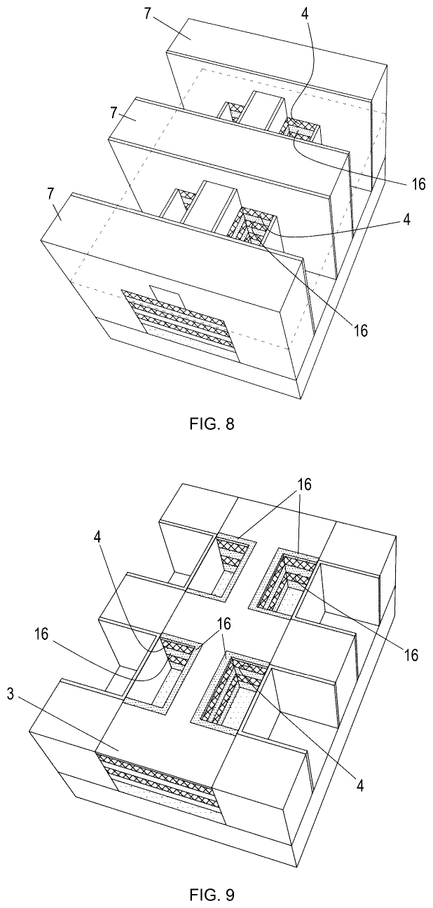

This may be then followed by the creation of inner spacers 16, with reference to FIGS. 8 and 9. Inner spacers can be formed by etching back the SiGe layers 3 laterally in the exposed U-shaped portions thereof to a depth of about 2-5 nm relative to the Si-layers 4 and replacing the removed SiGe by dielectric spacer material, which may be the same as the material of the gate spacers 8. The section view in FIG. 9 visualizes the inner spacers 16 in terms of the depth to which they extend between the Si layers 4. Inner spacers can be included in order to reduce the parasitic capacitance between the gate and the source or drain of the eventual transistor.

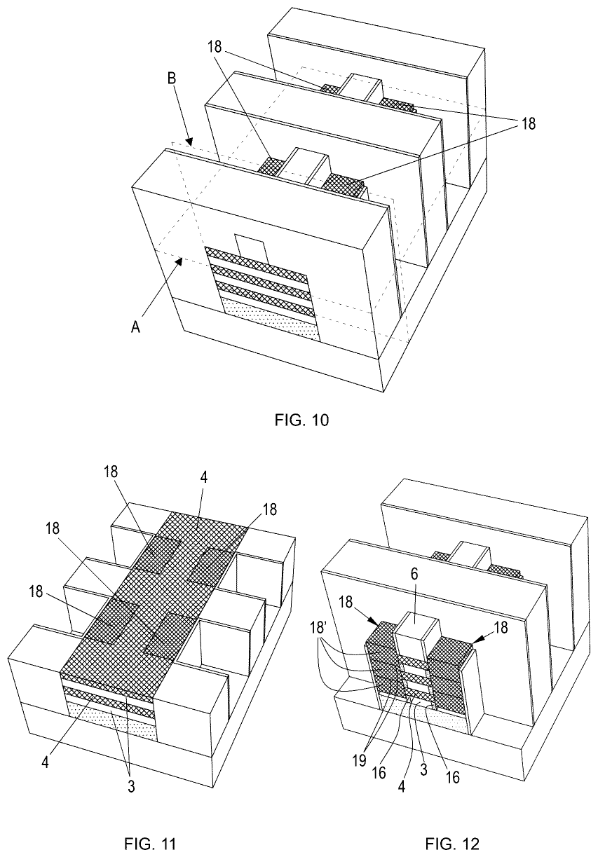

A potential next step is illustrated in FIGS. 10-12. Source and drain areas of eventual transistors can be formed between the dummy gate structures 7, by epitaxial growth of semiconductor material starting from the 3 Si-surfaces of each of the exposed U-shaped sidewalls 15 of the lateral recesses 14. The semiconductor material can be lattice-mismatched relative to Si. For example, for the production of pMOS nanosheet transistors, compressive stress can be required to optimize the carrier mobility in the channel. In this case, the source and drain areas may be formed of SiGe which has the appropriate lattice mismatch relative to Si to create the compressive stress. When growing SiGe between adjacent dummy gates, a dislocation plane appears which could neutralize the strain within the SiGe, thereby making it impossible to create the desired compressive channel stress.

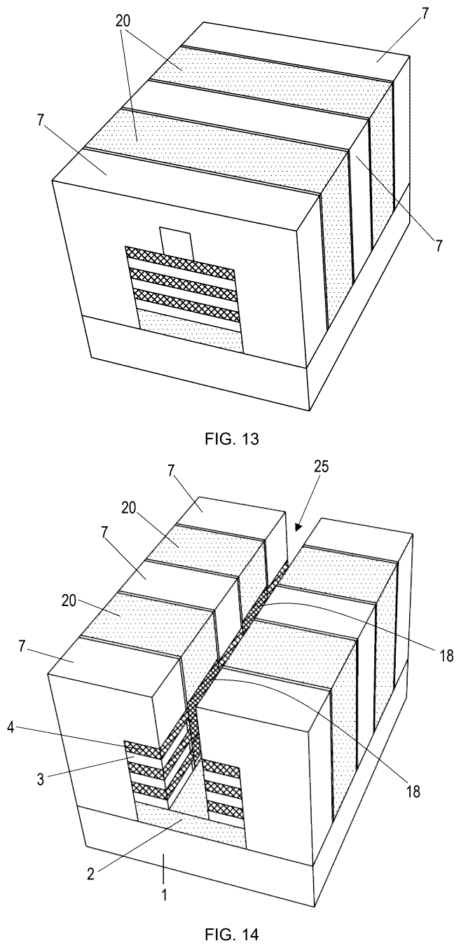

As visualized in the section in FIG. 11 by plane A parallel to the base substrate 1, each of the U-shaped Si surfaces can be part of a continuous crystalline structure 4. The material grown from the U-shaped Si surfaces can be also crystalline and fully strained because of the lattice mismatch and because the growth fronts advancing from the U-shaped Si sidewall portions do not interact with any opposite growth fronts, and can be therefore dislocation-free. As visible in the section by plane B perpendicular to the base substrate 1 in FIG. 12, an epitaxially grown volume 18 can be obtained in the recesses 14. In FIG. 12, it is seen that each volume 18 can be an agglomerate of subvolumes 18′ growing outward from the three U-shaped Si surfaces on the sidewall of a recess 14, the subvolumes 18′ merging along horizontal interfaces 19, while the lower subvolume can be spaced apart slightly from the SiO₂ layer 2. The volumes 18 may also fill the recesses 14 down to the bottom thereof.

Each Si layer 4 together with the volumes 18′ grown on the side surfaces thereof may be uniformly crystalline, i.e. they form a uniformly crystalline structure that can be strained because of the lattice mismatch between the Si layers 4 and the grown material 18′. The epitaxially grown volumes 18 obtained in this way can be thereby able to induce stress in the Si channels of the eventual transistors, wherein the volumes 18 can play the part of source or drain areas. Appropriate doping elements (e.g. p dopants in the case of a pMOS) may be added to the volumes 18′ during the epitaxial growth process, in view of the intended source/drain functionality.

Reference is made to FIG. 13. Dielectric material 20 can be deposited, completely filling the spaces between the dummy gates 7, and covering the structures between the dummy gates. The dielectric 20 can be then planarized to a common level with the dummy gates 7. The dielectric used may be any dielectric suitable as a so-called interlayer dielectric (ILD) used for isolating the connections to gate, source and drain areas of nano-sheet transistors. It may be for example a low-k dielectric. In the embodiment shown, the ILD material 20 must be different from and selectively removable with respect to the material of the spacers 8, given that this material can again be removed relative to the spacers at a later stage of the process (see further).

An additional patterning step can be then performed, with reference to FIG. 14. By lithography and anisotropic etching, a trench 25 can be formed through the dummy gates 7 and the SiGe/Si stack 3,4 of the original fin-shaped structure 5. The trench 25 extends in the longitudinal direction of the fin-shaped structure 5. The trench 25 can be wider than the mask 6 but narrower than the SiGe/Si stack 3,4 so that the trench cuts the SiGe/Si stack in two possibly equal parts, by removing the mask 6 and (if present) the spacers 8 on the sides thereof. The anisotropic etch can stop on the SiO₂ layer 2 by applying this layer as an etch stop layer or by a timed etch. On the sidewalls of the trench 25, portions of the original SiGe layers 3 and Si layers 4 can be exposed, interspaced with the epitaxially grown volumes 18. Each of the volumes 18 can be formed as an agglomerate of subvolumes 18′ which can form a uniformly crystalline structure with the Si layers 4 from which they can be grown.

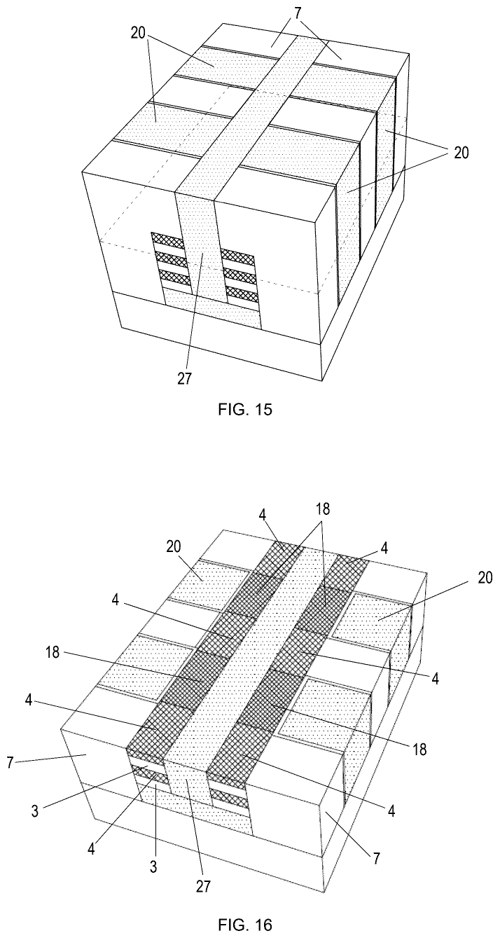

As illustrated in FIG. 15, a further layer of ILD material can be deposited, which may be the same material as the material 20 deposited previously. The further ILD layer can fill the trench 25 and can be subsequently planarized to a common level with the dummy gates 7. The section view in FIG. 16 illustrates that the obtained structure can be suitable for producing a forksheet configuration of nanosheet transistors. The ILD-filled trench 25 can form a dielectric wall 27, with on either side thereof, a plurality of SiGe/Si stacks 3,4 interspaced by epitaxially grown volumes 18.

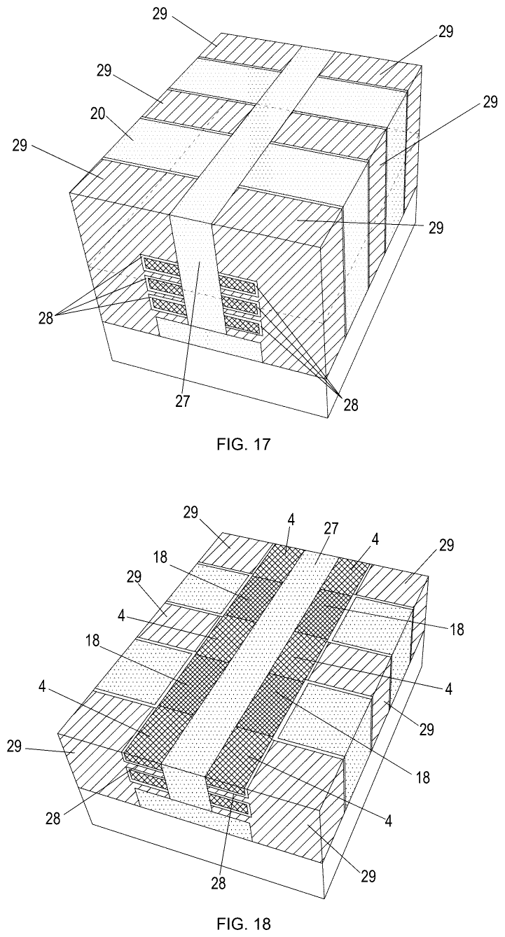

From the process stage shown in FIGS. 15 and 16, process steps for producing fully operational nanosheet transistors may be performed. This may include removing the dummy gate structures 7 and thereafter removing the sacrificial SiGe layers 3 relative to the Si layers 4, so that the Si layers 4 may be suspended as parallel sheets between two epitaxially grown volumes 18. With reference to FIGS. 17 and 18, dielectric layers 28 can be then formed on the exposed surface of each of the Si-layers 4 and a metal gate 29 can be formed around the dielectric layers 28. As seen in the section view in FIG. 18, multiple pairs of two transistors can be obtained from this configuration, one on each side of the dielectric wall 27, each transistor comprising source or drain areas 18, a channel formed of three parallel Si-sheets 4, and a metal gate 29 separated from the channel by a gate dielectric 28. The gates 29 can be cut and connections to any number of source/drain areas 18 and gates 29 can be produced according to a given interconnection layout, thereby creating one or more operational transistors.

If not more than 3 dummy gates would be produced and only one fin-shaped structure 5, the method would lead to just two groups of a gate, source and drain on either side of the dielectric wall 27 and hence to potentially two transistors, which may be the minimal configuration obtainable by the method. Within the present context, a ‘transistor’ can be defined as such if the source, drain and gate are effectively contacted by electrical conductors coupled to a supply voltage or to another transistor or other device. So theoretically the methods described herein can be capable of producing just one transistor in the above sense, if in the minimal configuration only one transistor is contacted. Therefore, the method can be suitable for producing ‘one or more transistors’. Of course, in most practical implementations the number of dummy gates and fin-shaped structures can be considerably higher, and the method enables the production of a large number of transistors. It is possible that not all of the gate, source and drain areas may effectively be contacted.

In the embodiment described above, the transistors can be formed on an isolation layer 2. This could be beneficial because it ensures that the epitaxial growth for creating the source and drain areas 18 initiates only on the sidewalls of the recesses 14 and not on the bottom thereof, which may be the case if the transistors were built directly on a crystalline semiconductor wafer. When the growth also starts from the bottom of the recesses, this growth may interfere with the lateral growth fronts and thereby lead to dislocations. However, depending on the material of the base substrate 1 and the number of semiconductor nanosheets 4 in the initial stack, it may be possible that the bottom-up growth does not have a large impact on the lateral growth so that a major part of the source and drain areas may be fully strained, and thereby able to create stress in one or more of the channel sheets. The production of transistors directly on a semiconductor substrate by the methods described herein is therefore not excluded from the scope.

In the embodiment shown in the drawings and described in detail hereabove, the hardmask 6 can be formed on the fin-shaped structure 5 prior to the formation of the dummy gates 7. In an alternative embodiment, the dummy gates may be formed directly on the fin-shaped structure 5 and the mask 6 may be either a hardmask or a resist mask (i.e. a softmask) produced after the formation of the dummy gates. The function of the mask can be the same as described above, regardless of the mask type or the stage in the process at which it is produced to cover a longitudinal portion of the fin-structure 5 in order to create the lateral cavities 14 as shown in FIGS. 6 and 7. Also, the mask, regardless of when and how it is produced, can be removed when the longitudinal trench 25 is produced, as illustrated in FIG. 14.

A nanosheet transistor produced by the methods described herein can be recognized by the fact that in any cross section parallel to the base substrate 1 and through at least one of the channel sheets 4, the source and drain areas 18 and the channel sheet 4 may be uniformly crystalline, i.e. substantially no dislocations appear within the cross section. The ‘at least one’ is included to take into account embodiments of transistors processed directly on a semiconductor substrate, in which case a lower portion of the source and drain could include dislocations as explained in the previous paragraph. When the transistor is formed on a dielectric layer 2 however, the source and drain and the channel may be uniformly crystalline in any cross section passing through any of the channel sheets 4. This may be because the cross sections pass through a channel sheet 4 and through the volumes 18′ grown directly on the side surfaces of the semiconductor layers 4 during the methods described herein, as described above.

Nanosheet transistors produced as described herein can be integrated in any integration scheme, including schemes wherein complementary pMOS and nMOS transistors are built one on top of the other, also known as the CFET integration (complementary field effect transistors). The configuration illustrated in the drawings could for example be used to produce pMOS transistors on a bottom isolation layer 2 lying on a Si process wafer 1. Starting from the image shown in FIG. 18, a layer of dielectric material may be produced on the planarized surface and nMOS transistors can then be produced on the dielectric layer, referred to as a the ‘middle dielectric layer’ of a CFET configuration, by the same method steps as described above, but using different materials given the fact that the stress requirements for an nMOS transistor can be different from a pMOS transistor.

While the present disclosure has been illustrated and described in detail in the drawings and foregoing description, such illustration and description are to be considered illustrative or exemplary and not restrictive. Other variations to the disclosed embodiments can be understood and effected by those skilled in the art in practicing the claimed invention, from a study of the drawings, the disclosure and the appended claims. In the claims, the word “comprising” does not exclude other elements or steps, and the indefinite article “a” or “an” does not exclude a plurality. The mere fact that certain measures are recited in mutually different dependent claims does not indicate that a combination of these measures cannot be used to advantage. Any reference signs in the claims should not be construed as limiting the scope.

While some embodiments have been illustrated and described in detail in the appended drawings and the foregoing description, such illustration and description are to be considered illustrative and not restrictive. Other variations to the disclosed embodiments can be understood and effected in practicing the claims, from a study of the drawings, the disclosure, and the appended claims. The mere fact that certain measures or features are recited in mutually different dependent claims does not indicate that a combination of these measures or features cannot be used. Any reference signs in the claims should not be construed as limiting the scope.

What is claimed is:

1. A method for producing one or more nano-sheet transistors, comprising:
on a base substrate, producing at least one fin-shaped structure extending in a longitudinal direction, the structure comprising a stack of layers including one or more sacrificial layers and one or more crystalline semiconductor layers formed of a first semiconductor material, stacked in alternating order;
producing at least three mutually parallel and spaced apart dummy gate structures arranged transversely with respect to and fully overlapping the fin-shaped structure and a mask;
producing dielectric spacers at least on sidewalls of the dummy gate structures;
patterning the stack of sacrificial and semiconductor layers by removing the material of the layers relative to the dummy gate structures and the spacers, and relative to a mask formed prior to or after producing the dummy gate structures and extending in the same longitudinal direction as the fin-shaped structure, so that two lateral recesses having U-shaped sidewalls are formed in the stack on each side of at least one of the dummy gate structures having adjacent dummy gates on either side, the sidewalls comprising exposed U-shaped portions of the sacrificial and semiconductor layers;
on the U-shaped sidewalls, producing inner spacers by etching back an exposed sacrificial material relative to an exposed semiconductor material, and replacing removed sacrificial material by a dielectric material;
by epitaxial growth, growing a second semiconductor material in the lateral recesses, wherein the second semiconductor material is lattice mismatched with respect to the first semiconductor material, the second semiconductor material grows outward starting from the exposed U-shaped portions of the layers of the first semiconductor material, the growth continues until a volume of the second semiconductor material is obtained in each of the lateral recesses;
producing a dielectric layer that fills the spaces between every pair of adjacent dummy gate structures and planarizing the dielectric layer to a common level with the dummy gate structures;
by lithography and etching, producing a trench along the longitudinal direction of the fin-shaped structure, the trench cutting through the dummy gate structures and the spacers, the trench being wider than the mask but narrower than the fin-shaped structure, so that the mask is removed while leaving portions of the stack of alternating sacrificial and first semiconductor layers on either side of the trench;
filling the trench with a dielectric material, thereby forming a dielectric wall;
removing the dummy gate structures and the remaining parts of the sacrificial layers, producing gate dielectric layers on the remaining parts of the first semiconductor layers and producing metal gates in direct contact with the gate dielectric layers on both sides of the dielectric wall; and
producing electrical connections to at least one metal gate and two epitaxially grown volumes directly adjacent and on either side of the gate, thereby obtaining at least one nano-sheet transistor comprising a channel, a source area and a drain area.

2. The method of claim 1, wherein the fin-shaped structure comprises a dielectric layer directly on the base substrate and wherein the stack of alternating sacrificial and semiconductor layers is formed directly on the dielectric layer.

3. The method of claim 1, wherein spacers are also formed on the sidewalls of the mask and on the sidewalls of the fin-shaped structure.

4. The method of claim 1, wherein the stack of alternating sacrificial and semiconductor layers comprises at least two semiconductor layers and wherein one epitaxially grown volume is formed in each of the recesses, the volume being obtained by merged subvolumes growing outward from respective exposed U-shaped portions of the semiconductor layers.

5. The method of claim 1, wherein the dielectric layer that fills the spaces between every pair of adjacent dummy gate structures is removed after producing the trench, and wherein a continuous layer of dielectric material is thereafter produced, the continuous layer filling the trench and the spaces between every pair of adjacent dummy gate structures.

6. The method of claim 1, wherein the mask is a hardmask formed on the fin-shaped structure and covering a central elongate portion of the structure, and wherein the hardmask is formed prior to producing at least three mutually parallel and spaced apart dummy gate structures arranged transversely with respect to and fully overlapping the fin-shaped structure and the mask.

7. The method of claim 1, wherein the mask is a hardmask formed after producing at least three mutually parallel and spaced apart dummy gate structures arranged transversely with respect to and fully overlapping the fin-shaped structure and the mask and covering a central elongate portion of the fin-shaped structure.

8. The method of claim 1, wherein the mask is a resist mask formed after producing at least three mutually parallel and spaced apart dummy gate structures arranged transversely with respect to and fully overlapping the fin-shaped structure and the mask and covering a central elongate portion of the fin-shaped structure.

9. A forksheet configuration, comprising:
a base substrate;
a dielectric wall; and
two nanosheet transistors on opposite sides of the dielectric wall, each of the transistors comprising one or more channel sheets, a metal gate, a gate dielectric between the channel sheets and the metal gate, a source and a drain area, characterized in that in any cross section parallel to the base substrate and through at least one of the channel sheets, the source and drain areas and the channel sheet through which the cross section is taken are uniformly crystalline.

10. The configuration according to claim 9, wherein a dielectric layer lies directly on the base substrate and wherein the dielectric wall and the transistors are placed on the dielectric layer.

11. A semiconductor component comprising one or more transistors produced according to the method of claim 1.

12. A semiconductor component comprising one or more transistors produced according to the method of claim 2.

13. A semiconductor component comprising one or more transistors produced according to the method of claim 3.

14. A semiconductor component comprising one or more transistors produced according to the method of claim 4.

15. A semiconductor component comprising one or more transistors produced according to the method of claim 5.

16. A semiconductor component comprising one or more transistors produced according to the method of claim 6.

17. A semiconductor component comprising one or more transistors produced according to the method of claim 7.

18. A semiconductor component comprising one or more transistors produced according to the method of claim 8.

19. A semiconductor component comprising one or more forksheet configurations according to the method of claim 9.

20. A semiconductor component comprising one or more forksheet configurations according to the method of claim 10.
